(19) United States
(12) Patent Application Publication
(10) Pub. No.: US 2025/0181272 A1
(43) Pub. Date: Jun. 5, 2025

(54) MEMORY CONTROLLER, STORAGE DEVICE, AND HOST-STORAGE SYSTEM

(71) Applicant: Samsung Electronics Co., Ltd., Suwon-si (KR)

(72) Inventor: Dong Eun SHIN, Suwon-si (KR)

(73) Assignee: Samsung Electronics Co., Ltd., Suwon-si (KR)

(21) Appl. No.: 18/906,725

(22) Filed: Oct. 4, 2024

(30) Foreign Application Priority Data
Dec. 4, 2023 (KR) 10-2023-0172967

(51) Int. Cl. G06F 3/06

(52) U.S. Cl. CPC G06F 3/0659; G06F 3/0613; G06F 3/0679

(57) ABSTRACT

Memory controller, storage device, and host-storage system are provided. The memory controller comprises a cache manager configured to receive a logical block address (LBA) from a host and to separate the LBA into at least a first LPN and a second LPN, a physical striper configured to output a first signal that corresponds the first LPN to a first page of a nonvolatile memory (NVM) device and corresponds the second LPN to a second page of the NVM device, and a logical writer configured to receive the first and second LPNs from the cache manager, to receive the first signal from the physical striper, and to store data to the NVM device, wherein the write operation includes a first write operation for first data to a first address of the NVM device and then performs a second write operation for second data to a second address of the NVM device.

### CROSS-REFERENCE TO RELATED APPLICATION

This application claims priority from Korean Patent Application No. 10-2023-0172967 filed on Dec. 4, 2023 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a memory controller, a storage device, and a host-storage system.

### 2. Description of the Related Art

Semiconductor memory devices are storage devices implemented using semiconductors such as silicon (Si), germanium (Ge), gallium arsenide (GaAs), indium phosphide (InP), etc. Semiconductor memory devices are largely categorized into volatile memory devices and nonvolatile memory devices.

Volatile memory devices are memory devices in which the data stored is not maintained (e.g., erased) when the power supply is interrupted. Examples of volatile memory devices include static random-access memories (SRAMs), dynamic random-access memories (DRAMs), and synchronous DRAMs (SDRAMs). Nonvolatile memory devices are memory devices that retain the stored data even when the power supply is interrupted. Examples of nonvolatile memory devices include read-only memories (ROMs), programmable ROMs (PROMs), electrically programmable ROMs (EPROMs), electrically erasable and programmable ROMs (EEPROMs), flash memory devices, phase-change RAMs (PRAMs), magnetic RAMs (MRAMs), resistive RAMs (RRAMs), and ferroelectric RAMs (FeRAMs or FRAMs). Read and write operations are typically slower for nonvolatile memory devices compared to volatile memory devices.

Meanwhile, if the time required to read data stored in a nonvolatile memory device is uneven, the read performance of the corresponding nonvolatile memory device may be evaluated poorly, leading to a reduction in reliability in terms of the read performance of that nonvolatile memory device.

### SUMMARY

Aspects of the present disclosure provide a memory controller that enhances the data read performance for a storage device.

Aspects of the present disclosure also provide a storage device with an improved reliability in terms of data read performance.

Aspects of the present disclosure also provide a host-storage system including storage device with an improved reliability in terms of data read performance.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a memory controller comprising a cache manager configured to receive a logical block address (LBA) from a host and to separate the LBA into a plurality of logical page numbers (LPNs), the plurality of LPNs including at least a first LPN and a second LPN; a physical striper configured to output a first signal that corresponds the first LPN to a first page of a nonvolatile memory device and corresponds the second LPN to a second page of the nonvolatile memory device, wherein the second page is different from the first page; and a logical writer configured to receive the first and second LPNs from the cache manager, to receive the first signal from the physical striper, and to store data to the nonvolatile memory device by performing a write operation based on the first signal, wherein the write operation includes a first write operation for first data to a first address of the nonvolatile memory device corresponding to the first LPN and then performs a second write operation for second data to a second address of the nonvolatile memory device corresponding to the second LPN, and wherein the data is stored such that a read operation by the host includes a first read operation for the first data stored at the first address and then a second read operation for the second data stored at the second address.

According to an aspect of the present disclosure, there is provided a storage device comprising a nonvolatile memory device including a memory cell array, and a memory controller configured to receive a write request signal and data from a host and control the nonvolatile memory device to write the received data to the memory cell array, wherein the nonvolatile memory device includes first through third pages, the memory controller includes a cache manager configured to receive a logical block address (LBA) from the host and to separate the LBA into a plurality of logical page numbers (LPNs), the plurality of LPNs including at least first through sixth LPNs, a physical striper is configured to perform a grouping operation such that a first group, including the first through third LPNs, and a second group including the fourth through sixth LPNs are generated, the first through third LPNs respectively correspond to the first through third pages and the fourth through sixth LPNs respectively correspond to the first through third pages, and a logical writer configured to receive the LPNs from the cache manager and to sequentially write first through sixth data, of the received data and respectively corresponding to the first through sixth LPNs, to the nonvolatile memory device by performing a write operation based on the grouping operation.

According to an aspect of the present disclosure, there is provided a host-storage system comprising a host configured to transmit a write request signal, data, and a logical block address (LBA); a nonvolatile memory device including a memory cell array and a plurality of word lines connected to the memory cell array; and a memory controller configured to receive the write request signal, the data, and the LBA and to control a write operation to write the data to a memory cell, of the nonvolatile memory device, corresponding to the LBA, wherein the memory controller includes a cache manager configured to separate the LBA into logical page numbers (LPNs), a logical writer configured to receive the one or more LPNs and to generate a program unit by collecting the LPNs on a page-by-page basis, and a physical striper configured to group some of the LPNs into a first LPN group and some of a remainder of the LPNs into a second LPN group such that the first LPN group corresponds to a first page and the second LPN group corresponds to a second page different from the first page, and wherein, when performing the write operation to the nonvolatile memory device based on the program unit, the logical writer is configured to initiate a write operation for the first page and then initiate a write operation for the second page before completing the write operation for the first page.

It should be noted that the effects of the present disclosure are not limited to those described above, and other effects of the present disclosure will be apparent from the following description.

Specific details of other embodiments are included in the detailed description and drawings.

### BRIEF DESCRIPTION OF THE DRAWINGS

The above and other aspects and features of the present disclosure will become more apparent by describing in detail example embodiments thereof with reference to the attached drawings, in which:

FIG. 1 is an illustrative diagram of a host-storage system according to some embodiments of the inventive concepts.

FIG. 2 is an illustrative diagram of the memory controller of FIG. 1.

FIG. 3 is an illustrative diagram of the nonvolatile memory device of FIG. 1.

FIG. 4 is an illustrative diagram of the memory controller and nonvolatile memory device of FIG. 1.

FIG. 5 is an illustrative diagram of the memory controller, memory interface, and nonvolatile memory device of FIGS. 1 and 2.

FIG. 6 is an illustrative diagram of a memory cell array according to some embodiments of the inventive concepts.

FIG. 7 is an illustrative diagram for explaining a sequential write operation for a nonvolatile memory device according to some embodiments of the inventive concepts.

FIGS. 8 and 9 are illustrative diagrams for explaining a mapping table showing the correspondence between logical addresses and physical addresses in the nonvolatile memory device according to some embodiments of the inventive concepts during a write operation.

FIG. 10 is an illustrative diagram for explaining threshold voltage distributions for different numbers of bits that can be stored in memory cells of the nonvolatile memory device according to some embodiments of the inventive concepts.

FIG. 11 is an illustrative diagram for explaining the memory controller of FIG. 2.

FIG. 12 is an example flowchart for explaining the write operation of the memory controller of FIG. 11.

FIGS. 13 through 16 are illustrative diagrams for explaining program units generated by the logical writer of FIG. 11 and the grouping operation performed by the physical striper of FIG. 11.

FIGS. 17 and 18 are illustrative diagrams for explaining how to write data to a nonvolatile memory device in an HSP scheme.

FIGS. 19 and 20 are illustrative diagrams for explaining groups generated by a grouping operation performed by a physical striper according to some embodiments of the inventive concepts.

FIGS. 21 through 24 are illustrative diagrams for explaining how to write data in a storage device according to some embodiments of the inventive concepts in a 2-8 HSP scheme.

FIG. 25 is an illustrative diagram for explaining a system to which a storage device according to some embodiments of the inventive concepts is applied.

### DETAILED DESCRIPTION

Memory controllers, storage devices, and host-storage systems according to some embodiments of the present disclosure will hereinafter be described with reference to the accompanying drawings.

In the disclosure, any of the elements and/or functional blocks disclosed, including those including “unit”, “ . . . er/or,” “logic”, etc., may be used to denote a unit that has at least one function or operation and is implemented with processing circuitry including hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components. Furthermore, line connections or connection members between elements depicted in the drawings represent functional connections and/or physical or circuit connections by way of example, and in actual applications, they may be replaced or embodied as various additional functional connections, physical connections or circuit connections.

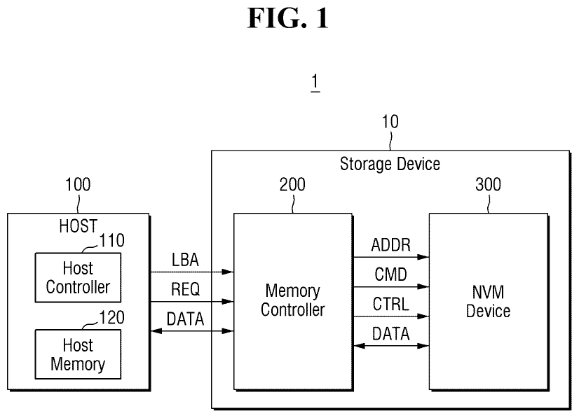

FIG. 1 is an illustrative diagram of a host-storage system according to some embodiments of the inventive concepts.

Referring to FIG. 1, a host-storage system 1 may include a host 100 and a storage device 10. The host 100 and the storage device 10 may be configured to be communication through an electrical (and/or similar) connection. For example, the host 100 and the storage device 10 may be electrically connected. The host 100 may provide logical block addresses (LBAs) “LBA” and request signals REQ to the storage device 10, and the host 100 and the storage device 10 may exchange data DATA based on the signals received from the host 100. For example, the host 100 may be connected to and/or communicate with a memory controller 200.

The host 100 may include, for example, a personal computer (PC), a laptop computer, a mobile phone, a smartphone, a tablet PC, a server, etc. The host 100 may include a host controller 110 and a host memory 120.

The host controller 110 may be configured to manage operations such as storing data (e.g., write data) from the host memory 120 in a nonvolatile memory device 300 and/or storing data (e.g., read data) from the nonvolatile memory device 300 in the host memory 120.

The host memory 120 may be configured to function as a buffer memory for temporarily storing the data DATA to be transmitted to the storage device 10 or the data DATA received from the storage device 10.

In some embodiments, the host controller 110 and the host memory 120 may be implemented as separate semiconductor chips. Alternatively, in other embodiments, the host controller 110 and the host memory 120 may be integrated on the same semiconductor chip. For example, the host controller 110 may be one of multiple modules provided in an application processor, and the application processor may be implemented as a system-on-chip (SoC). Additionally, the host memory 120 may be an embedded memory within the application processor or a volatile memory or memory module placed on the outside of the application processor.

The storage device 10 may include the memory controller 200 and the nonvolatile memory device 300. The storage device 10 may be integrated as a single semiconductor device. For example, the storage device 10 may include an embedded Universal Flash Storage (UFS) memory device, an embedded Multi-Media Card (eMMC), a solid-state drive (SSD), and/or the like. Also, for example, the storage device 10 may include a detachable UFS memory card, a Compact Flash (CF) card, a Secure Digital (SD) card, a micro-SD card, a mini-SD card, an extreme Digital (xD) card, and/or a memory stick. If the storage device 10 may conform to the Non-Volatile Memory express (NVMe) standard, for example, when the storage device 10 is an SSD.

The nonvolatile memory device 300 may include a NAND flash memory, but the present disclosure is not limited thereto. The nonvolatile memory device 300 may also include a NOR flash memory and/or a resistive memory such as a PRAM, an MRAM, an FeRAM, and/or an RRAM.

The memory controller 200 is connected to the nonvolatile memory device 300 and may be configured to control the nonvolatile memory device 300. For example, the memory controller 200 may provide addresses ADDR, commands CMD, and control signals CTRL to the nonvolatile memory device 300 in response to the LBAs “LBA” and request signals REQ received from the host 100. In other words, the memory controller 200 may provide signals to the nonvolatile memory device 300 and may thereby control data to be written to and/or read from the nonvolatile memory device 300. Additionally, the memory controller 200 and the nonvolatile memory device 300 may exchange the data DATA.

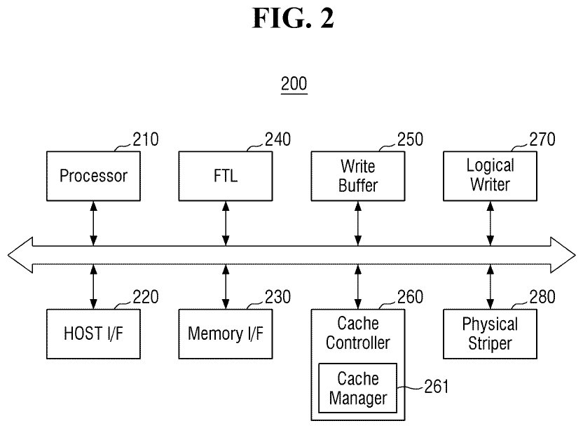

FIG. 2 is an illustrative diagram of the memory controller 200 of FIG. 1.

Referring to FIG. 2, the memory controller 200 may include a processor 210, a host interface 220, a memory interface 230, a flash translation layer (FTL) 240, a write buffer 250, a cache controller 260, a logical writer 270, and a physical striper 280. The memory controller 200 may further include other components than those depicted in FIG. 2.

The processor 210 may include a central processing unit (CPU), a controller, an application specific integrated circuit (ASIC), and/or the like. The processor 210 may be configured to control the overall operation of the memory controller 200. The processor 210 may run firmware loaded into the FTL 240 to control the memory controller 200.

The host interface 220 may be configured to transmit and receive packets from the host 100 of FIG. 1. Packets transmitted from the host 100 to the host interface 220 may include commands or data to be written to the nonvolatile memory 300 of FIG. 1. Packets transmitted from the host interface 220 to the host 100 may include responses to commands or data read from the nonvolatile memory device 300.

The memory interface 230 may be configured to transmit data to be written to the nonvolatile memory device 300 and/or receive data read from the nonvolatile memory device 300. The memory interface 230 may be implemented to comply with a standard protocol such as Toggle and/or Open NAND Flash Interface (ONFI).

The FTL 240 may be configured to include system software that manages the write, read, and erase operations of the nonvolatile memory device 300. For example, the FTL 240 may include firmware. The firmware in the FTL 240 may be executed by the processor 210. The FTL 240 may include software and/or hardware.

Th FTL 240 may be configured to perform various functions, such as address mapping, wear-leveling, garbage collection, and/or the like. Address mapping is an operation that involves converting logical addresses received from the host 100, such as the LBAs “LBA” of FIG. 1, or logical page numbers (LPNs), into physical addresses for use in actually storing data within the nonvolatile memory device 300.

Wear-leveling is a technique aimed at preventing (and/or reducing) excessive wear of particular blocks within the nonvolatile memory device 300 by ensuring uniform usage of blocks in the nonvolatile memory device 300, and may be implemented by, for example, firmware technology that balances the erase counts of physical blocks. Garbage collection is a technique used to reclaim available capacity within the nonvolatile memory device 300 by copying valid data from existing blocks to new blocks and then erasing the existing blocks.

The write buffer 250 may be configured to store code data necessary for the initial boot-up of the storage device 10. The write buffer 250 may buffer the LBAs “LBA”, the request signals REQ, the data DATA, and commands received from the host 100. The signals buffered in the write buffer 250 may be transmitted to the nonvolatile memory device 300 through the memory interface 230 and may then be utilized. For example, data DATA buffered in the write buffer 250 may be programmed into the nonvolatile memory device 300. In other words, the write buffer 250 may be a volatile memory device for temporarily storing the data DATA. Additionally, the write buffer 250 may also be a cache memory.

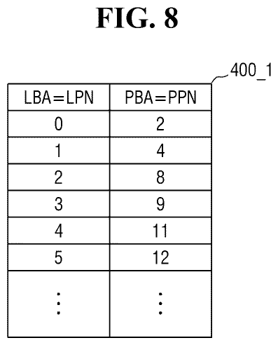

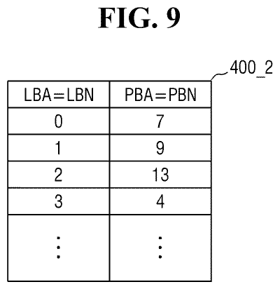

The cache controller 260 may be configured to control the write buffer 250. The cache controller 260 may regulate the overall operation of the write buffer 250 and control the caching operation for data DATA to be written to the nonvolatile memory device 300. The cache controller 260 may include a cache manager 261. The cache manager 261 may be configured to manage the caching operation of the write buffer 250. For example, the cache manager 261 may control data to be stored in the write buffer 250. Additionally, the cache manager 261 may receive the LBAs “LBA” from the host 100 and divide the received LBAs “LBA” into one or more LPNs. In other words, the cache manager 261 may classify (or separate) the received LBAs “LBA” into multiple LPNs. The relationship between the LPNs generated by the cache manager 261 and the LBAs “LBA” will be described later in detail with reference to FIGS. 8 and 9.

The logical writer 270 may be configured to receive LPNs from the cache manager 261 and to collect the received LPNs to create a program unit for performing a write operation on the nonvolatile memory device 300. For example, if one LPN is 4K and one program unit is 16K, the logical writer 270 may collect 4 LPNs to create one program unit. Then, the logical writer 270 may perform a write operation on the nonvolatile memory device 300 based on the generated program unit. The program unit may consist of a set of multiple pages within the nonvolatile memory device 300. The logical writer 270 may be configured to perform a write operation on the nonvolatile memory device 300 on a program unit-by-program unit basis.

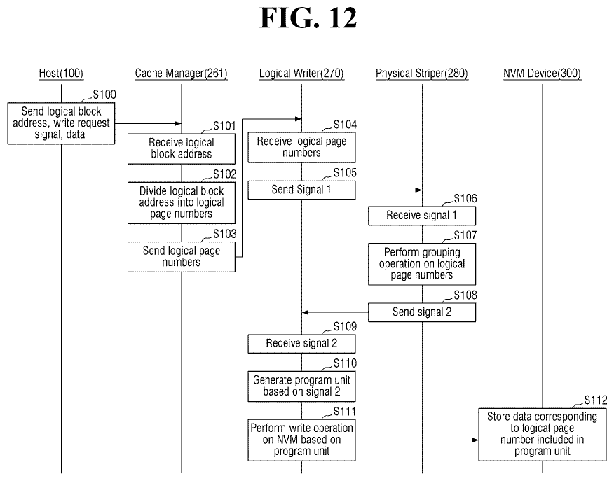

The physical striper 280 be configured to may transmit signals to the nonvolatile memory device 300 in response to signals received from the logical writer 270. The signals transmitted by the physical striper 280 may contain information regarding the correspondence between the received LPNs and the pages within the nonvolatile memory device 300. The physical striper 280 may correspond each LPN to one of the pages within the nonvolatile memory device 300 in consideration of the read pattern of the host 100 for the nonvolatile memory device 300. The logical writer 270 may create a program unit based on the signals received from the physical striper 280. The operations of the logical writer 270 and the physical stripper 280 will be described later in detail with reference to FIG. 12.

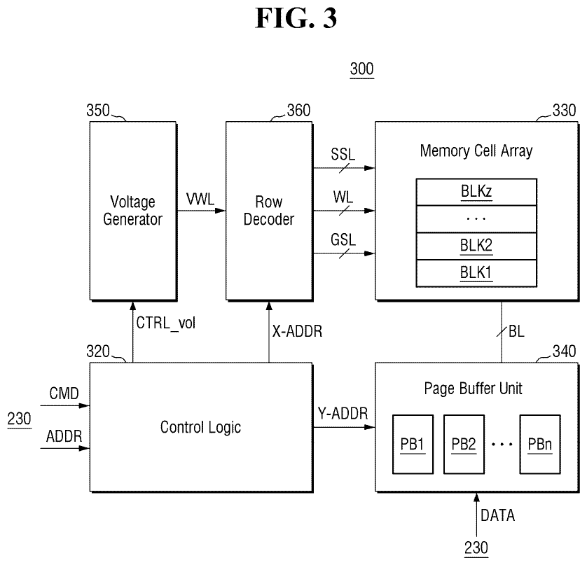

FIG. 3 is an illustrative diagram of the nonvolatile memory device of FIG. 1.

Referring to FIG. 3, the nonvolatile memory device 300 may include a control logic circuit 320, a memory cell array 330, a page buffer unit 340, a voltage generator 350, and a row decoder 360. The nonvolatile memory device 300 may further include column logic, a pre-decoder, a temperature sensor, a command decoder, an address decoder, etc. In at least one embodiment, the nonvolatile memory device 300 may also include the memory interface 230 of FIG. 2.

The control logic circuit 320 may be configured to generally control various operations within the nonvolatile memory device 300. The control logic circuit 320 may, for example, output various control signals in response to the commands CMD and/or addresses ADDR from the memory interface 230. For example, the control logic circuit 320 may output voltage control signals CTRL_vol, row addresses X-ADDR, and column addresses Y-ADDR corresponding to the commands CMD and/or the addresses ADDR. The voltage control signals CTRL_vol may include program signals or erase signals.

The memory cell array 330 may include a plurality of memory blocks BLK1 through BLKz (where z is a positive integer), and each of the memory blocks BLK1 through BLKz may include a plurality of memory cells. The memory cell array 330 may be connected to the page buffer unit 340 through bit lines BL and may also be connected to the row decoder 360 through word lines WL, string selection lines SSL, and ground selection lines GSL.

In at least one example embodiment, the memory cell array 330 may include a three-dimensional (3D) memory cell array, and the 3D memory cell array may include a plurality of NAND strings. Each of the NAND strings may include memory cells connected to respective word lines WL stacked vertically on a substrate. In other example embodiments, the memory cell array 330 may include a two-dimensional (2D) memory cell array, and the 2D memory cell array may include a plurality of NAND strings arranged in rows and columns.

The page buffer unit 340 may include a plurality of page buffers PB1 through PBn (where n is an integer greater than or equal to 3), and each of the page buffers PB1 through PBn may be connected to the memory cells through the bit lines BL. The page buffer PB1 will hereinafter be described as an example, and the description thereof may be directly applicable to the other page buffers PB2 through PBn.

The page buffer PB1 may be configured to select one of the bit lines BL in response to a column address Y-ADDR. The page buffer PB1 may operate as a write driver or a sense amplifier depending on operation mode. For example, during a program operation, the page buffer PB1 may apply a bit line volage corresponding to data to be programmed to the selected bit line BL, and during a read operation, the page buffer PB1 may sense the current or voltage of the selected bit line BL to detect data stored in the corresponding memory cells.

The voltage generator 350 may be configured to generate various types of voltages for performing program, read, and erase operations based on the voltage control signals CTRL_vol from the control logic circuit 320. For example, the voltage generator 350 may generate a program voltage, read voltage, program verification voltage, and erase voltage, as word line voltages VWL.

The row decoder 360 may be configured to select one of the word lines WL and one of the string selection lines SSL in response to a row address X-ADDR. For example, during a program operation, the row decoder 360 may apply the program voltage and program verification voltage to the selected word line WL, and during a read operation, the row decoder 360 may apply the read voltage to the selected word line WL.

The control logic circuit 320 may be connected to the voltage generator 350, the row decoder 360, and the page buffer unit 340. The control logic circuit 320 may be configured to control the operation of the nonvolatile memory device 300. For example, the control logic circuit 320 may operate in response to the control signals CTRL and commands CMD (e.g., write commands and read commands) provided from the memory controller 200 of FIG. 1.

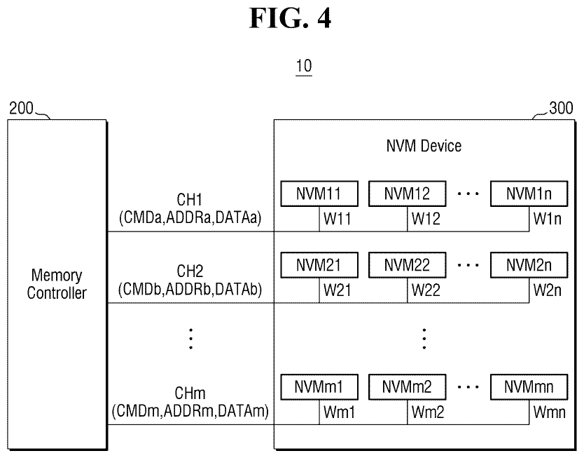

FIG. 4 is an illustrative diagram of the memory controller and nonvolatile memory device of FIG. 1.

Referring to FIG. 4, the storage device 10 may include the memory controller 200 and the nonvolatile memory device 300. The storage device 10 may support a plurality of first through m-th channels CH1 through CHm, and the memory controller 200 and the nonvolatile memory device 300 may be connected through the first through m-th channels CH1 through CHm. For example, the storage device 10 may be implemented as a storage device such as an SSD.

The nonvolatile memory device 300 may include a plurality of nonvolatile memory NVM11 through NVMmn. Each of the nonvolatile memory NVM11 through NVMmn may be connected to one of the first through m-th channels CH1 through CHm through a corresponding way. For example, the nonvolatile memory NVM11 through NVM1n may be connected to the first channel CH1 through ways W11 to W1n, and the nonvolatile memory NVM21 through NVM2n may be connected to the second channel CH2 through ways W21 to W2n. In at least one example embodiment, each of the nonvolatile memory NVM11 through NVMmn may be implemented as a memory unit configured to operate in responses to individual commands from the memory controller 200. For example, each of the nonvolatile memory NVM11 through NVMmn may be implemented as chips or dies, but the present disclosure is not limited thereto. In at least one embodiment, each of the nonvolatile memory NVM11 through NVMmn may include a memory cell array (“330” of FIGS. 3 and/or 6).

The memory controller 200 may be configured to transmit and/or receive signals to and from the nonvolatile memory device 300 through the first through m-th channels CH1 through CHm. For example, the memory controller 200 may transmit commands CMDa through CMDm, addresses ADDRa through ADDRm, and data DATAa through DATAm to the nonvolatile memory device 300 through the first through m-th channels CH1 through CHm or receive the data DATAa through DATAm from the nonvolatile memory device 300 through the first through m-th channels CH1 through CHm.

The memory controller 200 may be configured to select one of the nonvolatile memory NVM11 through NVMmn and transmit and receive signals to and from the selected nonvolatile memory device through the corresponding channel. For example, the memory controller 200 may select the nonvolatile memory NVM11, which is connected to the first channel CH1, and may transmit the command CMDa, address ADDRa, and data DATAa to the nonvolatile memory NVM11 through the first channel CH1 or receive the data DATAa from the nonvolatile memory NVM11 through the first channel CH1.

The memory controller 200 may be configured to transmit and/or receive signals to and from the nonvolatile memory device 300 in parallel through different channels. For example, while transmitting the command CMDa to the nonvolatile memory device 300 through the first channel CH1, the memory controller 200 may simultaneously transmit the command CMDb to the nonvolatile memory device 300 through the second channel CH2. Similarly, for example, while receiving the data DATAa from the nonvolatile memory device 300 through the first channel CH1, the memory controller 200 may receive the data DATAb from the nonvolatile memory device 300 through the second channel CH2.

The memory controller 200 may be configured to control the overall operation of the nonvolatile memory device 300. By transmitting signals to the first through m-th channels CH1 through CHm, the memory controller 200 may control each of the nonvolatile memory NVM11 through NVMmn connected to the first through m-th channels CH1 through CHm. For example, the memory controller 200 may transmit the command CMDa and the address ADDRa through the first channel CH1 and may thereby control one selected from among the nonvolatile memory devices NVM11 through NVM1n.

Each of the nonvolatile memory NVM11 through NVMmn may be configured to operate under the control of the memory controller 200. For example, the nonvolatile memory NVM11 may program the data DATAa based on the command CMDa, the address ADDRa, and the data DATAa provided through the first channel CH1. Similarly, for example, the nonvolatile memory NVM21 may be configured to read the data DATAb based on the command CMDb and the address ADDRa from the second channel CH2 and may transmit the read data DATAb to the memory controller 200.

Thus, as the memory controller 200 and the nonvolatile memory device 300 can transmit and receive the data DATAa through DATAm in parallel through the first through m-th channels CH1 through CHm, the read performance of the host 100 for the nonvolatile memory device 300 can be enhanced. For example, the memory controller 200 may simultaneously use channel resources by performing, in parallel, operations such as receiving the data DATAa from the nonvolatile memory NVM11 through NVM1n through the first channel CH1, receiving the data DATAb from the nonvolatile memory NVM21 through NVM2n through the second channel CH2, and receiving the data DATAm from the nonvolatile memory NVM1m through NVMmn through the m-th channel CHm. Consequently, the read performance of the host 100 for data stored in the nonvolatile memory device 300 can be improved compared to a case where the host 100 performs a read operation using only a subset of channel resources.

FIG. 4 illustrates the nonvolatile memory device 300 as communicating with the memory controller 200 through m channels and including n nonvolatile memory for each of the m channels, but the number of channels and the number of nonvolatile memories connected to each channel may vary.

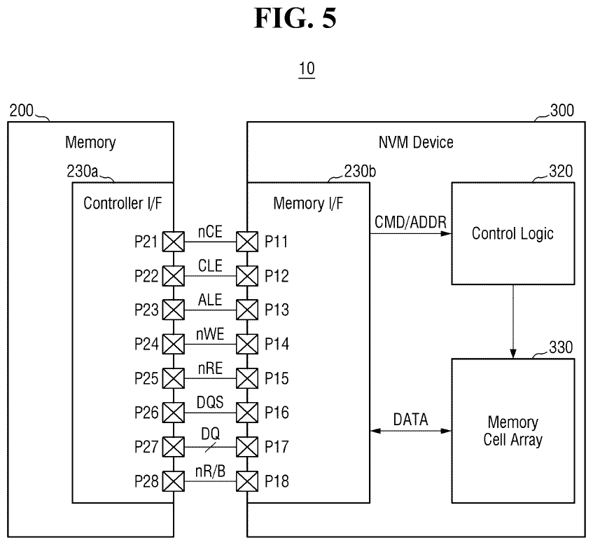

FIG. 5 is an illustrative diagram of the memory controller, memory interface, and nonvolatile memory device of FIGS. 1 and 2.

The nonvolatile memory device 300 may include first through eighth pins P11 through P18, a memory interface 230b, a control logic circuit 320, and a memory cell array 330.

The memory interface 230b may receive a chip enable signal nCE from the memory controller 200 through the first pin P11. The memory interface 230b may be configured to transmit in response to the chip enable signal nCE and to receive signals to and from the memory controller 200 through the second through eighth pins P12 through P18. For example, when the chip enable signal nCE is in an enabled state (or has a high level), the memory interface 230b may transmit and receive signals to and from the memory controller 200 through the second through eighth pins P12 through P18.

The memory interface 230b may receive a command latch enable signal CLE, an address latch enables signal ALE, and a write enable signal nWE from the memory controller 200 through the second through fourth pins P12 through P14. The memory interface 230b may also receive a data signal DQ from the memory controller 200 through the seventh pin P17 or transmit the data signal DQ to the memory controller 200 through the seventh pin P17. A command CMD, an address ADDR, and data DATA may be transmitted through the data signal DQ. For example, the data signal DQ may be transmitted through a plurality of data signal lines. In this case, the seventh pin P17 may include a plurality of pins corresponding to the data signal lines.

The memory interface 230b may acquire the command CMD for the command latch enable signal CLE from the data signal DQ, received during an enabled period (or a high-level period) of the command latch enable signal CLE, based on the toggle timings of the write enable signal nWE. Similarly, the memory interface 230b may acquire the address ADDR from the data signals DQ, received during an enabled period (e.g., a high-level period) of the address latch enable signal ALE, based on the toggle timings of the write enable signal nWE.

In some embodiments, the write enable signal nWE may maintain a static state (for example, a high level or a low level) and may then toggle between the high and low levels. For example, the write enable signal nWE may toggle during the transmission of the command CMD or address ADDR. Consequently, the memory interface 230b may acquire the command CMD or address ADDR based on the toggle timings of the write enable signal nWE.

The memory interface 230b may receive a read enable signal nRE from the memory controller 200 through the fifth pin P15. The memory interface 230b may receive and/or transmit a data strobe signal DQS from or to the memory controller 200 through the sixth pin P16.

During a data output operation of the nonvolatile memory device 300, the memory interface 230b may receive the toggling read enable signal nRE from the nonvolatile memory device 300 through the fifth pin P15 before the output of the data DATA. The memory interface 230b may be configured to generate the toggling data strobe signal DQS based on the toggling of the read enable signal nRE. For example, the memory interface 230b may generate the data strobe signal DQS that starts toggling after a predetermined delay (e.g., “tDQSRE”) following the beginning of the toggling of the read enable signal nRE. The memory interface 230b may transmit the data signal DQ, including the data DATA, based on the toggle timings of the data strobe signal DQS. Accordingly, the data DATA may be transmitted to the memory controller 200 in alignment with the toggling timings of the data strobe signal DQS.

During a data input operation of the nonvolatile memory device 300, when the data signal DQ, including the data DATA, is received from the memory controller 200, the memory interface 230b may receive the toggling data strobe signal DQS from the memory controller 200 together with the data DATA. The memory interface 230b may acquire the data DATA from the data signal DQ based on the toggling timings of the data strobe signal DQS. For example, the memory interface 230b may acquire the data DATA by sampling the data signal DQ at the rising and falling edges of the data strobe signal DQS.

The memory interface 230b may be configured to transmit a ready/busy output signal nR/B to the memory controller 200 through the eighth pin P18. For example, the memory interface 230b may transmit status information of the nonvolatile memory device 300 to the memory controller 200 through the ready/busy output signal nR/B. When the nonvolatile memory device 300 is in a busy state (e.g., when internal operations of the nonvolatile memory device 300 are in progress), the memory interface 230b may transmit the ready/busy output signal nR/B indicating the busy state to the memory controller 200. When the nonvolatile memory device 300 is in a ready state (e.g., when the internal operations of the nonvolatile memory device 300 are not in progress or have completed), the memory interface 230b may transmit the ready/busy output signal nR/B indicating the ready state to the memory controller 200.

For example, the memory interface 230b may be configured to transmit the ready/busy output signal nR/B indicating the busy state (e.g., a low-level state) to the memory controller 200 while the nonvolatile memory device 300 is reading the data DATA from the memory cell array in response to a page read command. For example, when the nonvolatile memory device 300 is programming the data DATA to the memory cell array 330 in response to a program command, the memory interface 230b may transmit the ready/busy output signal nR/B indicating the busy state to the memory controller 200.

The control logic circuit 320 may be configured to generally control various operations of the nonvolatile memory device 300. The control logic circuit 320 may receive a command/address (CMD/ADDR) acquired from the memory interface 230b. The control logic circuit 320 may generate control signals to control the other components of the nonvolatile memory device 300 in response to the received command/address CMD/ADDR. For example, the control logic circuit 320 may be configured to generate various control signals to program the data DATA into the memory cell array 330 or to read the data DATA from the memory cell array 330.

The memory cell array 330 may be configured to store the data DATA acquired from the memory interface 230b under the control of the control logic circuit 320. The memory cell array 330 may also output the stored data DATA to the memory interface 230b under the control of the control logic circuit 320.

The memory cell array 330 may include a plurality of memory cells. For example, the memory cells may be flash memory cells, but the present disclosure is not limited thereto. Alternatively, the memory cells may be RRAM cells, FRAM cells, PRAM cells, thyristor random-access memory (TRAM) cells, or MRAM cells. For convenience, the memory cells will hereinafter be described as being NAND flash memory cells.

The memory controller 200 may include first through eighth pins P21 through P28 and a controller interface 230a. The first through eighth pins P21 through P28 may correspond to the first through eighth pins P11 through P18 of the nonvolatile memory device 300.

The controller interface 230a may be configured to transmit the chip enable signal nCE to the nonvolatile memory device 300 through the first pin 1 P21. The controller interface 230a may transmit signals to and receive signals from the nonvolatile memory device 300 selected by the chip enable signal nCE, through the second through eighth pins P22 through P28.

The controller interface 230a may be configured to transmit the command latch enable signal CLE, the address latch enable signal ALE, and the write enable signal nWE to the nonvolatile memory device 300 through the second through fourth pins P22 through P24; and/or the controller interface 230a may transmit and/or receive the data signal DQ to or from the nonvolatile memory device 300 through the seventh pin P27.

The controller interface 230a may be configured to transmit the data signal DQ, including the command CMD or the address ADDR, to the nonvolatile memory device 300 together with the toggling write enable signal nWE. The controller interface 230a may transmit the data signal DQ, including the command CMD, to the nonvolatile memory device 300 by transmitting the enabled command latch enable signal CLE. Similarly, the controller interface 230a may transmit the data signal DQ, including the address ADDR, to the nonvolatile memory device 300 by transmitting the enabled address latch enable signal ALE.

The controller interface 230a may be configured to transmit the read enable signal nRE to the nonvolatile memory device 300 through the fifth pin P25. The controller interface 230a may also receive and/or transmit the data strobe signal DQS from or to the nonvolatile memory device 300 through the sixth pin P26.

During the data output operation of the nonvolatile memory device 300, the controller interface 230a may be configured to generate a read enable signal nRE that initiates a toggle and to transmits the toggling read enable signal nRE to the nonvolatile memory device 300. For example, the controller interface 230a may generate the toggling read enable signal nRE that changes from a fixed state (e.g., the high- or low-level state) to a toggling state before the output of the data DATA. Consequently, a data strobe signal DQS that toggles based on the toggling read enable signal nRE is generated in the nonvolatile memory device 300. The controller interface 230a may receive the data signal DQ, including the data DATA, from the nonvolatile memory device 300 together with the data strobe signal DQS that toggles. The controller interface 230a may acquire the data DATA from the data signal DQ based on the toggle timings of the data strobe signal DQS.

During the data input operation of the nonvolatile memory device 300, the controller interface 230a may generate a data strobe signal DQS that toggles. For example, the controller interface 230a may generate a data strobe signal DQS that changes from a fixed state (e.g., the high- or low-level state) to a toggling state before the transmission of the data DATA. The controller interface 230a may transmit the data signal DQ, including the data DATA, to the nonvolatile memory device 300 based on the toggle timings of the data strobe signal DQS.

The controller interface 230a may receive the ready/busy output signal nR/B from the nonvolatile memory device 300 through the eighth pin P28. The controller interface 230a may determine the status of the nonvolatile memory device 300 based on the ready/busy output signal nR/B.

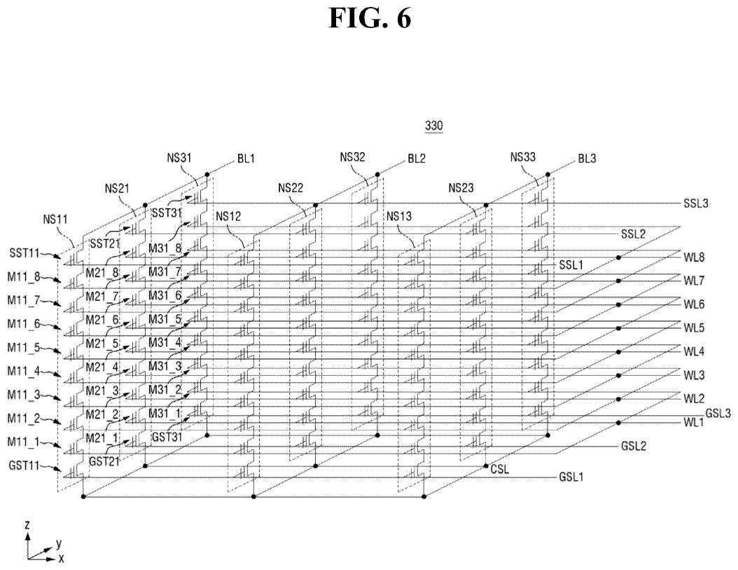

FIG. 6 is an illustrative diagram of a memory cell array according to some embodiments.

Referring to FIG. 6, a plurality of cell strings NS11, NS21, NS31, NS12, NS22, NS32, NS13, NS23, and NS33 may be arranged on a substrate in first and second directions x and y. The cell strings NS11, NS21, NS31, NS12, NS22, NS32, NS13, NS23, and NS33 may extend in a third direction z. The cell strings NS11, NS21, NS31, NS12, NS22, NS32, NS13, NS23, and NS33 may be commonly connected to a common source line CSL formed on or within the substrate. FIG. 6 illustrates the common source line CSL as being connected to the lowest portions of the cell strings NS11, NS21, NS31, NS12, NS22, NS32, NS13, NS23, and NS33 in the third direction z. However, it is sufficient for the common source line CSL to be only electrically connected to the lowest portions of the cell strings NS11, NS21, NS31, NS12, NS22, NS32, NS13, NS23, and NS33 in the third direction z, and the common source line CSL may not necessarily be located at the bottoms of the cell strings NS11, NS21, NS31, NS12, NS22, NS32, NS13, NS23, and NS33. Additionally, FIG. 6 illustrates the cell strings NS11, NS21, NS31, NS12, NS22, NS32, NS13, NS23, and NS33 as being arranged in a 3×3 array, but the arrangement and number of cell strings disposed in a memory cell array 330 are not particularly limited.

The cell strings NS11, NS12, and NS13, may be connected to a first ground select line GSL1. The cell strings NS21, NS22, and NS23 may be connected to a second ground select line GSL2. The cell strings NS31, NS32, and NS33 may be connected to a third ground select line GSL3.

Additionally, the cell strings NS11, NS12, and NS13 may be connected to a first string select line SSL1. The cell strings NS21, NS22, and NS23 may be connected to a second string select line SSL2. The cell strings NS31, NS32, and NS33 may be connected to a third string select line SSL3.

Each of the cell strings NS11, NS21, NS31, NS12, NS22, NS32, NS13, NS23, and NS33 may include a string select transistor SST connected to the corresponding string select line. Each of the cell strings NS11, NS21, NS31, NS12, NS22, NS32, NS13, NS23, and NS33 may also include a ground select transistor GST connected to the corresponding ground select line.

Each of the cell strings NS11, NS21, NS31, NS12, NS22, NS32, NS13, NS23, and NS33 may be connected to the corresponding ground select transistor once. Furthermore, a plurality of memory cells may be sequentially stacked in the third direction z between the ground select transistor and the string select transistor of each of the cell strings NS11, NS21, NS31, NS12, NS22, NS32, NS13, NS23, and NS33. Although not specifically illustrated, dummy cells may also be included between the ground select transistor and the string select transistor of each of the cell strings NS11, NS21, NS31, NS12, NS22, NS32, NS13, NS23, and NS33. Additionally, the number of strings select transistors included in each of the cell strings NS11, NS21, NS31, NS12, NS22, NS32, NS13, NS23, and NS33 is not particularly limited.

For example, the cell string NS11 may include a ground select transistor GST11, which is located at the lowest portion, in the third direction z, of the cell string NS11, and a plurality of memory cells M11_1 through M11_8, which are sequentially stacked in the third direction z on top of the ground select transistor GST11, and a string select transistor SST11, which is stacked in the third direction z on top of the memory cell M11_8. Similarly, the cell string NS21 may include a ground select transistor GST21, which is located at the lowest point, in the third direction z, of the cell string NS21, and a plurality of memory cells M21_1 through M21_8, which are sequentially stacked in the third direction z on top of the ground select transistor GST21, and a string select transistor SST21, which is stacked in the third direction z on top of the memory cell M21_8. Additionally, the cell string NS31 may include a ground select transistor GST31, which is located at the lowest point, in the third direction z, of the cell string NS31, and a plurality of memory cells M31_1 to M31_8, which are sequentially stacked in the third direction z on top of the ground select transistor GST31, and a string select transistor SST31, which is stacked in the third direction z on top of the memory cell M31_8. The other cell strings may also have similar configurations.

Memory cells located at the same height in the third direction z from the substrate or their respective ground select transistors may be electrically connected through their respective word lines. For example, the memory cells M11_1, M21_1, and M31_1 may be connected to a first word line WL1. Similarly, the memory cells M11_2, M21_2, and M31_2 may be connected to a second word line WL2. Memory cells connected to each of word lines WL3 through WL8 may also have similar configurations, and thus, detailed descriptions thereof will be omitted.

One end of the string select transistor of each of the cell strings NS11, NS21, NS31, NS12, NS22, NS32, NS13, NS23, and NS33 may be connected to one of first through third bit lines BL1 through BL3. For example, the string select transistors SST11, SST21, and SST31 may be connected to the first bit line BL1, which extends in the second direction y. Similarly, other string select transistors may be connected to their corresponding bit lines, and thus, descriptions thereof will be omitted.

Memory cells corresponding to the same string (or ground) select line and the same word line may form one page. A write or read operation may be performed on a page-by-page basis. Memory cells of each page may each store two or more bits. Bits written to memory cells in each page may form a logical page.

The memory cell array 330 may be provided as a 3D memory array. The 3D memory array may be monolithically formed on a substrate and/or one or more physical levels of arrays of memory cells having active regions placed over circuits associated with the operations of the memory cells. The circuits associated with the operations of the memory cells may be positioned on or within the substrate. The expression “monolithically formed” means that each level of layers of the 3D memory array may be deposited directly on their respective underlying levels of layers. Alternatively, the circuits associated with the operations of the memory cells may be connected to uppermost contact portions in the third direction z.

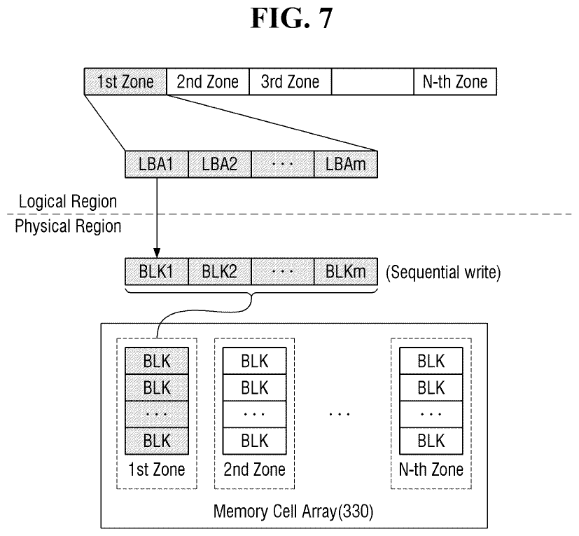

FIG. 7 is an illustrative diagram for explaining a sequential write operation for a nonvolatile memory device according to some embodiments of the inventive concepts.

Referring to FIG. 7, in some embodiments, the logical writer (“270” of FIG. 2) of the memory controller 200 of FIG. 1 may perform a sequential write operation on the nonvolatile memory device 300. Referring to FIG. 7, a zone may conceptually refer to some physically sequential portions from the memory blocks (“BLK1” through “BLKz” of FIG. 3) of the nonvolatile memory device 300 of FIG. 1. For example, the memory controller 200 and the nonvolatile memory device 300 may support the Nonvolatile Memory Express (NVMe) Zoned NameSpace (ZNS) standard. Within one memory cell array 330, there may exist a plurality of zones, for example, first through N-th zones (where N is an arbitrary natural number). For a better understanding, FIG. 7 illustrates both logical and physical regions of each of the first through N-th zones.

Referring to the logical region, the memory controller 200 may manage the first through N-th zones. The first through N-th zones may be managed independently. For example, the host 100 of FIG. 1 may run first and second applications. The first application may manage data included in the first zone. The second application may manage data included in the second zone. That is, data with similar purposes and usage cycles, managed by the same application, may be managed within the same zone.

Each of the first through N-th zones may include a plurality of LBAs. For example, the first zone may include first through m-th LBAs LBA1 through LBAm (where m is a natural number). The first through m-th LBAs LBA1 through LBAm may be logically sequential.

Logical regions may include logical addresses that are identifiable by the host 100. Physical regions may include the locations or addresses of memory blocks BLK within the nonvolatile memory device 300. The logical regions and the physical regions may have a mapping relationship therebetween. An address mapping operation that converts host-identifiable logical addresses into physical addresses within the nonvolatile memory device 300 may be performed by the FTL 240.

The host 100 may transmit the first through m-th LBAs LBA1 through LBAm to the storage device 10. The first through m-th LBAs LBA1 through LBAm may be logically sequential.

The memory controller 200 may sequentially store data in the memory cell array 330. For example, data corresponding to the first and second LBAs LBA1 and LBA2 may be sequentially written to the memory cell array 330. When the write buffer (“250” of FIG. 2) of the memory controller 200 stores data corresponding to the third LBA LBA3, the data corresponding to the third LBA LBA3 may be written to the memory cell array 330.

Referring to the physical region, the memory cell array 330 may include a plurality of memory blocks BLK. The memory blocks BLK may be categorized into the first through N-th zones. The memory blocks BLK within the first zone may be first through m-th memory blocks BLK1 through BLKm that are physically sequential. The first through m-th memory blocks BLK1 through BLKm of the first zone may correspond to the first through m-th LBAs LBA1 through LBAm, respectively, of the first zone. The memory controller 200 may manage data received from the host 100 to be sequentially stored logically and physically within the memory cell array 330. That is, the memory controller 200 may support sequential writing.

FIG. 7 illustrates that one LBA may correspond to one memory block BLK, but the inventive concepts are not limited thereto. For example, one LBA may correspond to one of multiple sequential sub-memory blocks within one memory block BLK while maintaining its logical sequence relative to other LBAs. Alternatively, one LBA may correspond to one of multiple sequential program units while maintaining its logical sequence relative to other LBAs. A program unit represents the unit of performing programming, .e.g., a write operation, on memory cells, and may correspond to a set of logical pages.

FIGS. 8 and 9 are illustrative diagrams for explaining a mapping table showing the correspondence between logical addresses and physical addresses in the nonvolatile memory device according to some embodiments of the inventive concepts during a write operation.

Referring to FIG. 8, a mapping table 400_1 may include LBAs and their corresponding physical block addresses (PBAs) within the nonvolatile memory device 300 of FIG. 1. For example, the LBAs may correspond to the LPNs of the host 100. Similarly, the PBAs may correspond to the physical page numbers (PPNs) of the nonvolatile memory device 300.

In other words, when the FTL 240 performs mapping at a page level, which means that read or write operations of the host 100 are performed in units of pages, the LBAs and the PBAs may correspond to the LPNs and the PPNs, respectively.

For example, when the memory controller 200 of FIG. 1 receives a write request signal for data corresponding to LBA 0 from the host 100, the memory controller 200 may store the received data at PPN 2 within the nonvolatile memory device 300 with reference to the mapping table 400_1.

Referring to FIG. 9, a mapping table 400_2 may include LBAs and their corresponding PBAs within the nonvolatile memory device 300. For example, the LBAs may be the LBNs of the host 100. Similarly, the PBAs may correspond to physical block numbers (PBNs) of the nonvolatile memory device 300. Each of the LBNs may encompass the concept of two or more LPNs as depicted in FIG. 8.

In other words, when the FTL 240 performs mapping at a block level, the host 100 performs a read or write operation in units of blocks and the LBAs and the PBAs may correspond to the LBNs and the PBNs, respectively.

For example, when the memory controller 200 of FIG. 1 receives a write request signal for data corresponding to LBA 0 from the host 100, the memory controller 200 may store the received data at PBA 7 within the nonvolatile memory device 300 with reference to the mapping table 400_2.

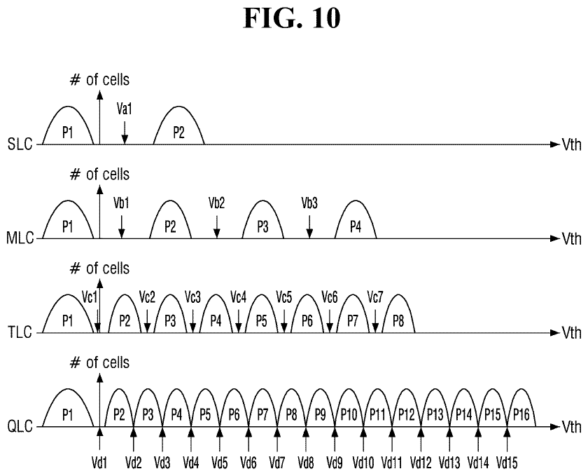

FIG. 10 is an illustrative diagram for explaining threshold voltage distributions for different numbers of bits that can be stored in memory cells of the nonvolatile memory device according to some embodiments of the inventive concepts.

Referring to FIG. 10, the horizontal axis of each graph represents the magnitude of a threshold voltage, and the vertical axis of each graph represents the number of memory cells. When the memory cells are single-level cells (SLCs) capable of storing 1-bit data, the memory cells may have a threshold voltage Vth corresponding to one of first and second programming states P1 and P2. A read voltage Val may be a voltage for distinguishing between the first and second programming states P1 and P2. Memory cells with the first programming state P1 have a lower threshold voltage Vth than the read voltage Val and may be read as on cells. Memory cells with the second programming state P2 have a higher threshold voltage Vth than the read voltage Val and may be read as off cells.

When the memory cells are multi-level cells (MLCs) capable of storing 2-bit data, the memory cells may have a threshold voltage Vth corresponding to one of first through fourth programming states P1 through P4. First through third read voltages Vb1 through Vb3 may be voltages for distinguishing between the first through fourth programming states P1 through P4.

When the memory cells are triple-level cells (TLCs) capable of storing 3-bit data, the memory cells may have a threshold voltage Vth corresponding to one of first through eighth programming states P1 through P8. The first through seventh read voltages Vcl through Vc7 may be voltages used to distinguish between the first through eighth programming states P1 through P8.

When the memory cells are quadruple-level cells (QLCs) capable of storing 4-bit data, the memory cells may have a threshold voltage Vth corresponding to one of first through sixteenth programming states P1 through P16. First through fifteenth read voltages Vd1 through Vd15 may be voltages for distinguishing between the first through sixteenth programming states P1 through P16.

In some embodiments, the nonvolatile memory device 300 of FIG. 1 may perform a high-speed programming (HSP) operation to quickly program data into MLCs. For example, when the nonvolatile memory device 300 programs data into TLCs, the HSP operation may include programming 3-bit data all at once by applying a gradually-increasing program voltage to the word lines WL using the row decoder 360 of FIG. 3 to sequentially form the first through eighth programming states P1 through P8.

Referring to FIG. 6, when 2 or more bits of data are stored in the memory cells, two or more pages may correspond to one word line WL of the memory cell array 330. For example, when the memory cells are MLCs, 2-bit data, (e.g., the most significant bit (MSB) data and the least significant bit (LSB) data) may be stored in each memory cell. Here, the MSB data may correspond to an MSB page, and the LSB data may correspond to an LSB page. In this case, two pages may correspond to one word line WL of the memory cell array 330.

Alternatively, when the memory cells are TLCs, three-bit data (e.g., including a MSB data, a central significant bit (CSB) data, and an LSB data) may be stored in each memory cell. Here, the MSB data may correspond to an MSB page, the CSB data may correspond to a CSB page, and the LSB data can correspond to an LSB page. In this case, three pages may correspond to one word line WL of the memory cell array 330.

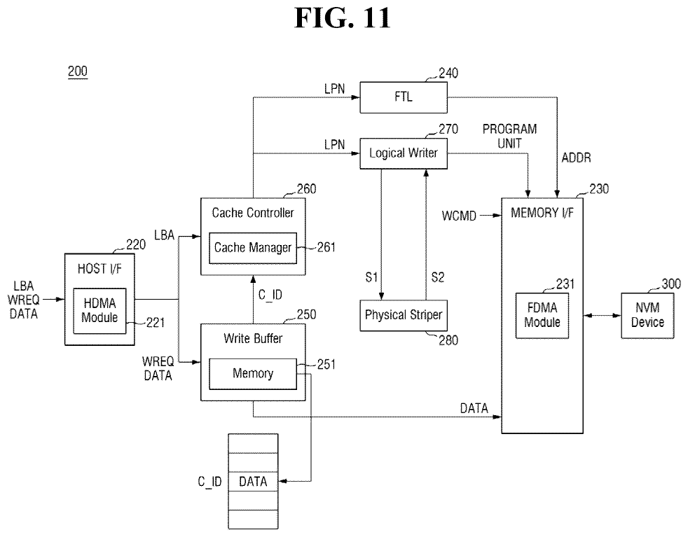

FIG. 11 is an illustrative diagram for explaining the memory controller of FIG. 2. Descriptions of the content that overlaps with what has been described above with reference to FIG. 2 will be omitted.

The host interface 220 may include a host direct memory access (DMA) module 221. The host interface 220 may receive an LBA “LBA”, a write request signal WREQ, and/or data DATA from the host 100 of FIG. 2. Here, the host interface 220 may receive and translate the LBA “LBA”, the write request signal WREQ, and the data DATA according to the NVMe standard. The host DMA module 221 may input the data DATA to the memory controller 200 using the LBA “LBA”, the write request signal WREQ, and the data DATA. The host DMA module 221 may manage DMA of the data DATA. In other words, the host DMA module 221 may manage the data DATA to be input directly to the write buffer 250 without passing through the processor 210 of FIG. 2, but the present disclosure is not limited thereto.

The write buffer 250 may include a memory 251. Here, the memory 251 may be a buffer memory. The write buffer 250 may buffer the data DATA received from the host 100.

That is, the write buffer 250 may temporarily store the data DATA in the memory 251 according to the write request signal WREQ. For example, the memory 251 may cache the data DATA. The memory 251 may temporarily store the data DATA based on a cache identifier C_ID. Here, the cache identifier C_ID may correspond to the address of the memory 251 where the data DATA is stored. Here, the write buffer 250 may be a volatile memory. In other words, the write buffer 250 may store the data DATA, only during and/or before the programming of the data DATA to the nonvolatile memory device 300, and may remove the data DATA after the programming of the data DATA to the nonvolatile memory device 300. Furthermore, the write buffer 250 may provide the buffered data DATA to the memory interface 230 or the nonvolatile memory device 300 in response to a request from the memory interface 230 or nonvolatile memory device 300.

The write buffer 250 may be configured to be controlled by the cache controller 260. Additionally, the write buffer 250 may provide the cache identifier C_ID1 of the memory 251 to the cache controller 260.

The cache controller 260 may be configured to register the LBA “LBA” and the cache identifier C_ID. The cache controller 260 may control the overall operation of the write buffer 250 and manage the caching operation for the data DATA. The cache controller 260 may include a cache manager 261.

The cache manager 261 may be configured to manage the caching operation of the write buffer 250. For example, the cache manager 261 may control the data DATA to be stored in the write buffer 250. The cache manager 261 may store the data DATA to correspond to the LBA “LBA” and the cache identifier C_ID. That is, in response to the write request WREQ for the LBA “LBA” being received from the host 100, the cache manager 261 may identify the cache identifier C_ID of the write buffer 250. Furthermore, when the address in the write buffer 250 where the data DATA is stored is updated, the cache manager 261 may store the updated address.

The FTL 240 may receive an LPN or LBA from the cache controller 260. Here, the FTL 240 may correspond to a working memory and may operate as firmware. The FTL 240 may convert the LPN into a physical address ADDR with reference to a mapping table. The FTL 240 may temporarily store the LPN and the corresponding address ADDR. The address ADDR may correspond to a physical address in the nonvolatile memory device 300.

The memory interface 230 may receive a write command WCMD, the address ADDR, and the data DATA. Here, the memory interface 230 may receive the address ADDR from the FTL 240 and the data DATA from the write buffer 250. The write buffer 250 may be configured to provide the buffered data DATA to the memory interface 230. Additionally, the memory interface 230 may access the data DATA stored in the memory 251. The flash DMA module 231 included in the memory interface 230 may control the access of the data DATA between the memory controller 200 and the nonvolatile memory device 300. In other words, the flash DMA module 231 may allow the data DATA stored in the memory 251 to be input to the nonvolatile memory device 300.

FIG. 12 is an example flowchart for explaining the write operation of the memory controller of FIG. 11. The write operation of the memory controller 200 will hereinafter be described with reference to FIG. 12 and may be referred as to including a grouping operation performed by a physical striper.

Referring to FIG. 12, the host 100 may provide an LBA, a write request signal, and data to the memory controller 200 (S100). That is, the host 100 may provide the LBA, the write request signal, and the data to the host interface 220.

The host interface 220 may transmit the LBA to the cache controller 260 and transmit the write request signal and the data to the write buffer 250. The cache manager 261 may receive the LBA from the host interface 220 (S101) and may divide the LBA into LPNs (S102). Here, the LPNs may correspond to a logical address that corresponds to a physical address in the nonvolatile memory device 300 where the data DATA is to be written by the host 100. Thereafter, the cache manager 261 may transmit the LPNs to the logical writer 270 (S103).

The logical writer 270 may receive the LPNs from the cache manager 261 (S104). Thereafter, the logical writer 270 may transmit a first signal S1 to the physical striper 280 (S105). Here, the first signal S1 may be a signal inquiring which page of the nonvolatile memory device 300 the LPNs received by the logical writer 270 correspond to.

The number of pages of the nonvolatile memory device 300 may be determined depending on the type of the memory cells included in the memory cell array 330 of the nonvolatile memory device 300. For example, when the memory cells in the memory cell array 330 are MLCs, the number of pages of the nonvolatile memory device 300 may be two (e.g., the MSB and LSB pages). Alternatively, when the memory cells in the memory cell array 330 are TLCs, the number of pages of the nonvolatile memory device 300 may be 3 (e.g., the MSB, CSB, and LSB pages).

That is, the logical writer 270 may inquire of the physical striper 280, through the first signal S1, which page of the nonvolatile memory device 300 the data corresponding to the received LPNs is to be stored in. Here, one LPN may correspond to one data, but the present disclosure is not limited thereto. Alternatively, depending on the mapping operation of the FTL 240, two or more LPNs may correspond to one data.

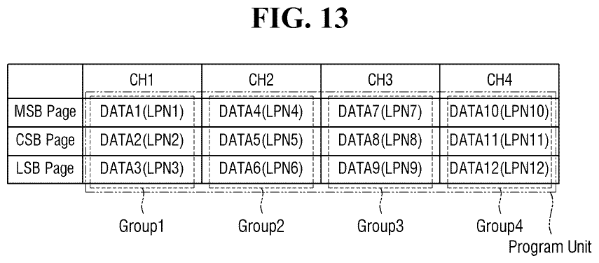

The physical striper 280 may receive the first signal S1 from the logical writer 270 (S106). In response to the first signal S1, the physical striper 280 may perform a grouping operation for the received LPNs (S107). The physical striper 280 may generate a second signal S2 including the correspondence between the LPNs received by the logical writer 270 and the pages of the nonvolatile memory device 300 through the grouping operation. The grouping operation will be described later with reference to FIGS. 13 through 15.

Thereafter, the physical striper 280 may transmit the second signal S2 to the logical writer 270 (S108), and the logical writer 270 may receive the second signal S2 (S109) and generate a program unit based on the second signal S2 (S110). Thereafter, the logical writer 270 may perform a write operation for the nonvolatile memory device 300 based on the program unit (S111). Accordingly, the nonvolatile memory device 300 may store data corresponding to the LPNs included in the program unit (S112).

FIGS. 13 through 16 are illustrative diagrams for explaining program units generated by the logical writer of FIG. 11 and the grouping operation performed by the physical striper of FIG. 11.

The memory cells in the memory cell array 330 will hereinafter be described as being, for example, TLCs, but the present disclosure is not limited thereto. For example, the following description may also be applicable to a case where the memory cells in the memory cell array 330 are MLCs.

Referring to FIG. 13, the nonvolatile memory device 300 may include three pages, e.g., MSB, CSB, and LSB pages. The nonvolatile memory device 300 may receive first through twelfth data DATA1 through DATA12 from the memory controller 200 through first through fourth channels CH1 through CH4. The number of channels between the memory controller 200 and the nonvolatile memory device 300 is not particularly limited and may vary. That is, the number of channels between the memory controller 200 and the nonvolatile memory device 300 may be greater or less than four. As explained earlier with reference to FIG. 7, the nonvolatile memory device 300 may perform a sequential write operation for the first through twelfth data DATA1 through DATA12. For example, the nonvolatile memory device 300 may write the first data DATA1 first, followed by the second through eleventh data DATA2 through DATA11 sequentially, and finally the twelfth data DATA12.

In some embodiments, the first through twelfth data DATA1 through DATA12 may correspond to first through twelfth LPNs LP1 through LPN12, respectively. For example, the first data DATA1 may be stored at an address in the nonvolatile memory device 300 corresponding to the first LPN LPN1 among the physical addresses in the nonvolatile memory device 300. Similar explanations are directly applicable to the other data and their respective LPNs, e.g., the second through twelfth data DATA2 through DATA12 and the second through twelfth LPNs LPN2 through LPN12, and will be omitted here.

The grouping operation performed by the physical striper 280 may involve assigning each of the first through twelfth LPNs LPN1 through LPN12, received by the logical writer 270, to one of the MSB, CSB, or LSB pages to create a plurality of groups, for example, first through fourth groups Group1 through Group4. The physical striper 280 may perform the grouping operation, considering the read pattern of the host 100 of FIG. 1.

For example, when the nonvolatile memory device 300 performs a sequential write operation for the first through twelfth data DATA1 through DATA12, the host 100 may sequentially read the first through twelfth data DATA1 through DATA12 from the nonvolatile memory device 300.

Therefore, since the first data DATA1 is to be written first, the host 100 may read the first data DATA1 first from the nonvolatile memory device 300. Similarly, since the twelfth data DATA12 is to be written finally, the host 100 may read the twelfth data DATA12 finally from the nonvolatile memory device 300.

In some embodiments, the physical striper 280 may assign the LPN of the first data DATA1, e.g., the first LPN LPN1, to, for example, the MSB page, and then assign the LPN of the second data DATA2, e.g., the second LPN LPN2, to another page, for example, the CSB page, but the present disclosure is not limited thereto. When the second LPN LPN2 is assigned to the CSB page, the physical striper 280 may assign the LPN of the third data DATA3, e.g., the fourth LPN LPN3, to the LSB page and may then assign the LPN of the fourth data DATA4, e.g., the fourth LPN LPN4, back to the MSB page.

In this manner, the physical striper 280 may assign the LPNs of the first through twelfth data DATA1 through DATA12 between the pages of the nonvolatile memory device 300 in such a manner that multiple data to be sequentially written may be assigned to different pages, assuming that the host 100 sequentially reads the corresponding data.

The logical writer 270 may create a program unit “Program Unit” for the first through fourth groups Group1 through Group4 based on the grouping operation performed by the physical striper 280.

FIG. 13 illustrates that the first through third data DATA1 through DATA3 to be sequentially written first are transmitted to the nonvolatile memory device 300 through one channel, for example, the first channel CH1, and then the fourth through sixth data DATA4 through DATA6 to be sequentially written next are transmitted to the nonvolatile memory device 300 through a subsequent channel, for example, the second channel CH2, but the present disclosure is not limited thereto.

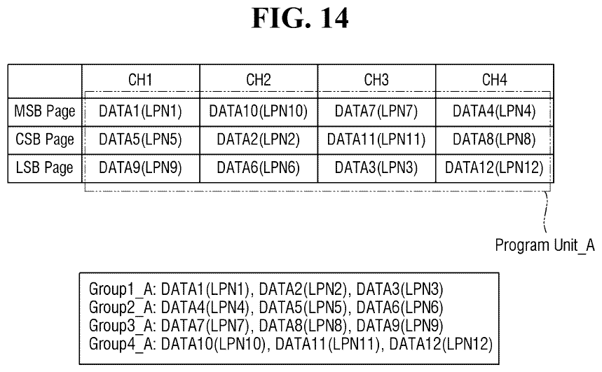

For example, referring to FIG. 14, when the physical striper 280 corresponds the first through twelfth LPNs LPN1 through LPN12 to the MSB, CSB, and LSB pages, the memory controller 200 may consider performing a striping operation for the nonvolatile memory device 300. That is, the memory controller 200 may provide data to the nonvolatile memory device 300 in a distributed manner to enhance the performance (e.g., write and/or read performance) of the storage device 10, and may allow the physical striper 280 to simultaneously utilize the first through fourth channels CH1 through CH4 to control the nonvolatile memory device 300 so that the data provided in the distributed manner may be programmed simultaneously.

Consequently, contrary to what has been described above with reference to FIG. 13, the physical striper 280 may transmit the first data DATA1 with the first LPN LPN1 assigned to the MSB page to the nonvolatile memory device 300 through the first channel CH1 and may then transmit data to be written next to the first data DATA1, e.g., the second data DATA2 with the second LPN LPN2 assigned to the CSB page, to the nonvolatile memory device 300 through another channel, for example, the second channel CH2. Thereafter, the physical striper 280 may transmit data to be written next to the second data DATA2, e.g., the third data DATA3 with the third LPN LPN3 assigned to the LSB page, to the nonvolatile memory device 300 through yet another channel, for example, the third channel CH3.

Thus, considering the read pattern of the host 100, the physical striper 280 may perform the grouping operation in such a manner that multiple data to be sequentially written, e.g., the first through twelfth data DATA1 through DATA12, may be as much distributed as possible between pages and between channels.

In this manner, the logical writer 270 may create a program unit Program Unit_A for first through fourth groups Group1_A through Group4_A obtained by the grouping operation performed by the physical striper 280.

In other words, FIG. 13 illustrates data transmitted to the nonvolatile memory device 300 through the same channel as being included in the same group, and FIG. 14 illustrates that the first, second, and ninth data DATA1, DATA2, and DATA9 transmitted to the nonvolatile memory device 300 through the first channel CH1 may be included in different groups; but the present disclosure is not limited thereto.

FIGS. 13 and 14 illustrate that data to be written one after another, for example, the first and second data DATA1 and DATA2, are assigned to different pages, e.g., the MSB and CSB pages, respectively, but the present disclosure is not limited thereto.

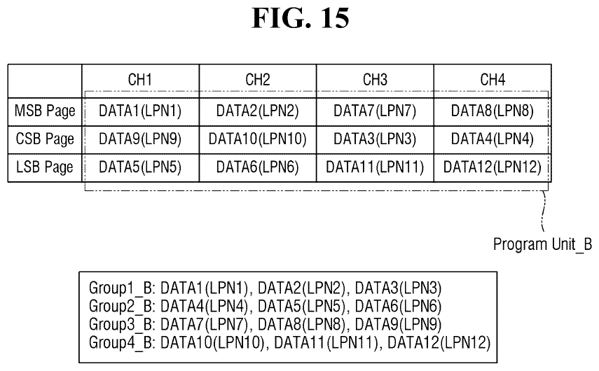

In some embodiments, the LPNs of two or more data to be sequentially written first may correspond to one page, and the LPNs of two or more data to be sequentially written next may correspond to another page. For example, referring to FIG. 15, the LPNs of the first and second data DATA1 and DATA2 to be sequentially written first, e.g., the first and second LPNs LPN1 and LPN2, may both correspond to the MSB page, and the LPNs of the third and fourth data DATA3 and DATA4 to be sequentially written next, e.g., the third and fourth LPNs LPN3 and LPN4, may both correspond to a different page from the first and second LPNs LPN1 and LPN2, for example, the CSB page. In this case, as a result of the striping operation performed by the memory controller 200, the first and second data DATA1 and DATA2 may be transmitted to the nonvolatile memory device 300 through the first and second channels CH1 and CH2, respectively, and the third and fourth data DATA3 and DATA4 may be transmitted to the nonvolatile memory device 300 through the third and fourth channels CH3 and CH4, respectively. Similarly, the other data and their respective LPNs, e.g., the fifth through twelfth data DATA5 through DATA12 and the fifth through twelfth LPNs LPN5 through LPN12, may correspond to one of the MSB, CSB, and LSB pages of the nonvolatile memory device 300, and the fifth through twelfth data DATA5 through DATA12 may be transmitted to the nonvolatile memory device 300 through one of the first through fourth channels CH1 through CH4.

In this manner, the logical writer 270 may create a program unit Program Unit_B for first through fourth groups Group1_B through Group4_B obtained by the grouping operation performed by the physical striper 280.

The program units Program Unit, Program Unit_A, and Program Unit_B of FIGS. 13 through 15 will hereinafter be described.

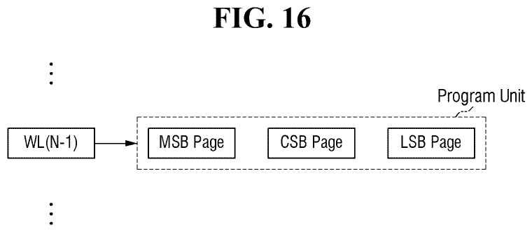

FIG. 16 is an illustrative diagram for explaining a program unit generated by a logical writer according to some embodiments of the inventive concepts.

Referring to FIG. 16, a program unit “Program Unit” may be any one of the program units “Program Unit”, Program Unit_A, and Program Unit_B of FIGS. 13 through 15. The program unit “Program Unit” will hereinafter be described as being the program unit “Program Unit_A” of FIG. 14.

In some embodiments, the program unit “Program Unit” may consist of three pages, e.g., MSB, CSB, and LSB pages, and the MSB, CSB, and LSB pages may be programmed onto one word line WL(N) within the memory cell array 330 of FIG. 6. The logical writer 270 may perform a write operation on a program unit-by-program unit basis (e.g., using write operation including a grouping operation performed by a physical striper) and may simultaneously program three-bit data (e.g., MSB, CSB, and LSB data) through an HSP operation.

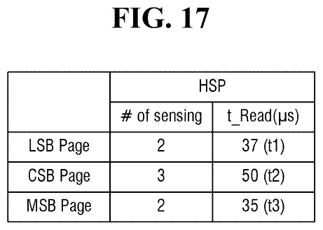

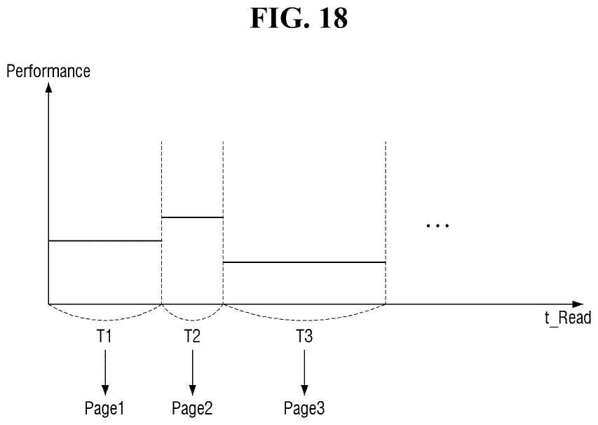

FIGS. 17 and 18 are illustrative diagrams for explaining how to write data to a nonvolatile memory device in a comparative HSP scheme.

Referring to FIG. 17, when data is written to the nonvolatile memory device 300 in the HSP scheme, there may arise variations in sensing counts and data read times t_Read between different pages.

The data read time t_Read may represent the amount of time that it takes from when the memory cell array 330 is activated to when data is read from the memory cells of the memory cell array 330 and reaches the page buffer unit 340. In other words, the data read time t_Read may mean the duration from the receipt of a read command and addresses in the memory interface 230 to when data is read from the memory cell array 330 and delivered to the page buffer unit 340.

For example, when reading data stored in the MSB page, the sensing may be performed twice, resulting in a data read time t_Read of 37 microseconds (μs). Similarly, when reading data stored in the CSB page, the sensing may be performed three times, resulting in a data read time t_Read of 50 μs. Likewise, when reading data stored in the LSB page, the sensing may be performed twice, resulting in a data read time t_Read of 35 μs. However, the sensing counts and data read times for different pages are not limited to those shown in FIG. 17 and may vary.

When the data read time t_Read differs from one page to another page, as mentioned earlier, the performance of a read operation may vary depending on which page the data currently being read is stored in when reading data stored in the nonvolatile memory device 300.

For example, referring to FIG. 18, in some comparative examples, the memory cell array 330 may include a first page Page1, a second page Page2, and a third page Page3, in which case, a data read time T3 for the third page Page3 may be longer than a data read time T1 for the first page Page1 and the data read time T1 for the first page Page1 may be longer than a data read time T2 for the second page Page2.

The length of a data read time may be inversely proportional to data read performance. For example, when reading data from the page with the shortest data read time T2, e.g., the second page Page2, the read performance of the storage device 10 of FIG. 1 may be rated the highest. Conversely, when reading data from the page with the longest data read time T3, e.g., the third page Page3, the read performance of the storage device 10 may be rated the lowest. Therefore, if the evaluation of the performance of the storage device 10 changes depending on which page of the memory cell array 330 is being read, the reliability of the performance of the storage device 10 may be degraded.

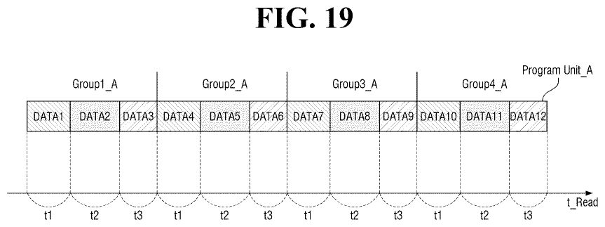

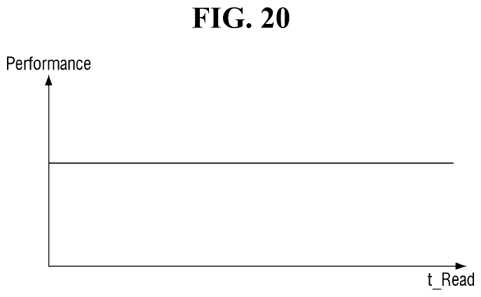

FIGS. 19 and 20 are illustrative diagrams for explaining groups generated by a grouping operation performed by a physical striper according to some embodiments of the inventive concepts.

The embodiment of FIGS. 19 and 20 will hereinafter be described, taking, as an example, the first through fourth groups Group1_A through Group4_A (of FIG. 14) generated by the physical striper 280 and the program unit Program Unit_A (of FIG. 14) generated by the logical writer 270. However, the following description of the embodiment of FIGS. 19 and 20 may also be applicable not only to the first through fourth groups Group1 through Group4 and the program unit “Program Unit” of FIG. 13, but also to the first through fourth groups Group1_B through Group4_B and the program unit Program Unit_B of FIG. 15.

The horizontal axis of FIG. 19 represents the data read time t_Read for each of the first through twelfth data DATA1 through DATA12. Referring to FIGS. 14, 17, and 19, the data read time t_Read for the MSB page is represented as t1, the data read time t_Read for the CSB page as t2, and the data read time t_Read for the LSB page as t3. The first through twelfth data DATA1 through DATA12 are data that are sequentially written, and may also be sequentially read. For example, the data belonging to the first group Group1_A, e.g., the first through third data DATA1 through DATA3, are sequentially read, then, the data belonging to the second group Group2_A, e.g., the fourth through sixth data DATA4 through DATA6, may be sequentially read, and finally, the data belonging to the third group Group3_A, e.g., the seventh through ninth data DATA7 through DATA9, may be sequentially read.

In this case, as the data belonging to each of the first through fourth groups Group1_A through Group4_A are stored in different types of pages, the sum of the data read times t_Read for the pages of each of the first through fourth groups Group1_A through Group4_A may almost be similar. For example, the data belonging to the first group Group1_A, e.g., the first through third data DATA1 through DATA3, are not stored in the same page but in different pages, e.g., the MSB, CSB, and LSB pages, respectively, and similarly, the data belonging to the second group Group2_A, e.g., the fourth through sixth data DATA4 through DATA6, are also stored in different pages, e.g., in the MSB, CSB, and LSB pages, respectively. Thus, the total data read time for the first group Group1_A may be similar to the total data read time for the second group Group2_A.

Accordingly, referring to FIG. 20, contrary to what has been described earlier with reference to FIG. 18, the data read performance of the storage device 10 may remain consistent regardless of which page of the memory cell array 330 is being read. Therefore, the reliability of the performance of the storage device 10 can be improved.

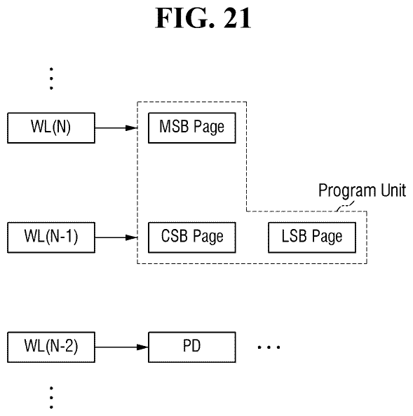

FIGS. 21 through 24 are illustrative diagrams for explaining how to write data in a storage device according to some embodiments of the inventive concepts in a 2-8 HSP scheme.

Referring to FIG. 21, contrary to what has been described earlier with reference to FIG. 16, three pages (e.g., MSB, CSB, and LSB pages) that form a program unit may be programmed between two word lines WL(N) and WL(N-1) within the memory cell array 330 of FIG. 6. For example, the MSB page may be programmed on the word line WL(N-1), and the CSB and LSB pages may be programmed on the word line WL(N), which is adjacent to the word line WL(N-1).

Also, a previous page PD may correspond to a word line WL(N-2). Other pages than the previous page PD may also correspond to the word line WL(N-2).

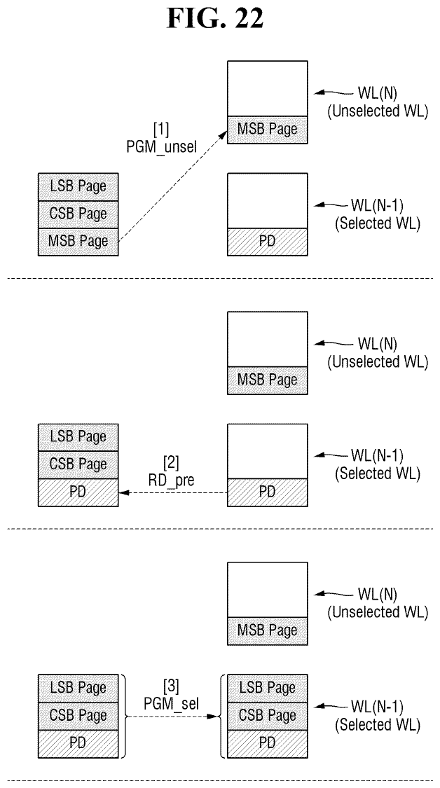

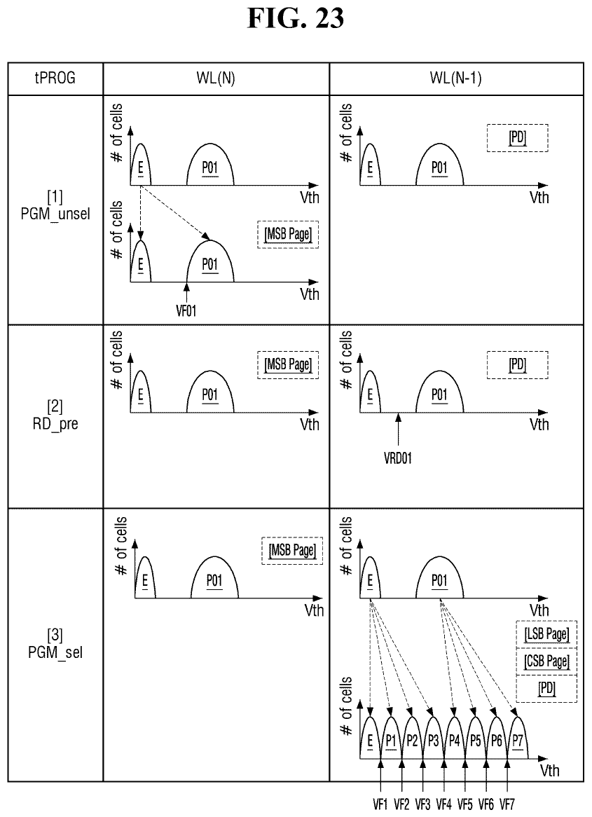

The 2-8 HSP manner that programs the three pages (e.g., MSB, CSB, and LSB pages) of a program unit between two word lines (e.g., the word lines WL(N) and WL(N-1)) within the memory cell array 330, as illustrated in FIG. 21, will hereinafter be described with reference to FIGS. 22 and 23.

For convenience, the description assumes that in a current program operation, the word line WL(N-1) may be a selected word line, whereas the word line WL(N) is an unselected word line, and that the word line WL(N-1) already stores the previous page PD. For example, before the program operation for the word line WL(N-1), a program operation for the word line WL(N-2) may be performed. In the program operation for the word line WL(N-2), the word line WL(N-2) is the selected word line, whereas the word line WL(N-1) is the unselected word line, and at least one of the pages corresponding to the word line WL(N-2), for example, the previous page PD, may be unselectively programmed onto the word line WL(N-1). That is, at the beginning of the program operation for the word line WL(N-1), the word line WL(N-1) may already store the previous page PD unselectively programmed during the previous program operation. However, the present disclosure is not limited thereto.

The nonvolatile memory device 300 of FIG. 1 may receive the MSB, CSB, and LSB pages corresponding to the word line WL(N-1). In at least one example embodiment, the received MSB, CSB, and LSB pages may be stored in the page buffer unit 340 (of FIG. 3) of the nonvolatile memory device 300. The nonvolatile memory device 300 may program one of the MSB, CSB, and LSB pages corresponding to the word line WL(N-1) onto the unselected word line, e.g., the word line WL(N) (e.g., perform an unselected program operation PGM_unsel).

For example, referring to FIG. 23, the nonvolatile memory device 300 may perform the unselected program operation PGM_unsel for the word line WL(N) such that the memory cells connected to the word line WL(N) may be placed in either an erase state E or unselected program state PO1. In at least one example embodiment, during the unselected program operation PGM_unsel, an unselected verification voltage VF01 may be used to verify the unselected program state P01. When the unselected program operation PGM_unsel for the word line WL(N) is complete, the word line WL(N) already stores a page corresponding to the word line WL(N-1), and the word line WL(N-1) already stores the previous page PD.

Thereafter, the nonvolatile memory device 300 may perform a previous page read operation RD_pre for the word line WL(N-1) to read the previous page PD. For example, as illustrated in FIG. 23, each memory cell in the word line WL(N-1) where the previous page PD is stored may have either the erase state E or the unselected program state PO1. By performing the previous page read operation RD_pre using a read voltage VRD01, the nonvolatile memory device 300 may read the previous page PD.

In at least one example embodiment, the previous page PD read by the previous page read operation RD_pre may be stored in a particular latch in the page buffer unit 340 of the nonvolatile memory device 300. The particular latch may refer to a data latch where the page (e.g., the MSB page) programmed onto the unselected word line. That is, after the previous page read operation RD_pre, the page buffer unit 340 of the nonvolatile memory device 300 may store the LSB and CSB pages corresponding to the word line WL(N-1) and the previous page PD corresponding to the word line WL(N-2).

Thereafter, the nonvolatile memory device 300 may perform a selected program operation PGM_sel for the word line WL(N-1) based on the LSB and CSB pages and the previous page PD. For example, as previously described, after the completion of the previous page read operation RD_pre, the page buffer unit 340 of the nonvolatile memory device 300 may store the LSB and CSB pages and the previous page PD. Then, the nonvolatile memory device 300 may perform the selected program operation PGM_sel for the word line WL(N-1) based on the LSB and CSB pages and previous page PD stored in the page buffer unit 340.

As a result of the execution of the selected program operation PGM_sel, memory cells in the word line WL(N-1) previously in the erased state E may have one of the erase state E and first through third program states P1 through P3, while memory cells in the word line WL(N-1) previously in the unselected program state PO1 may have one of fourth through seventh program states P4 through P7. During the selected program operation PGM_sel, first through seventh verification voltages VF1 through VF7 may be used to verify the first through seventh program states P1 through P7. This type of program method may be referred to as a 2-8 HSP scheme, and the technical concept of the present disclosure may be applicable to the 2-8 HSP scheme.

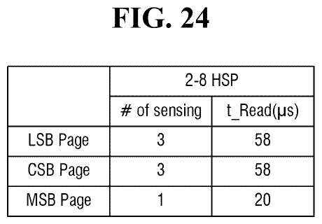

For example, referring to FIG. 24, the 2-8 HSP scheme may exhibit larger variations in sensing counts and data read times t_Read between pages compared to the HSP scheme described earlier with reference to FIG. 17. Consequently, the reliability of the read performance of the storage device 10 may be further compromised with the 2-8 HSP scheme in comparison to the HSP scheme depicted in FIG. 17. Thus, when programming data in the nonvolatile memory device 300 according to the 2-8 HSP scheme, the physical striper 280 may perform a grouping operation to ensure that multiple data to be sequentially written in accordance with the previous embodiments are assigned to different pages. Based on the results of the grouping operation, the logical writer 270 may collect LPNs to generate a program unit.

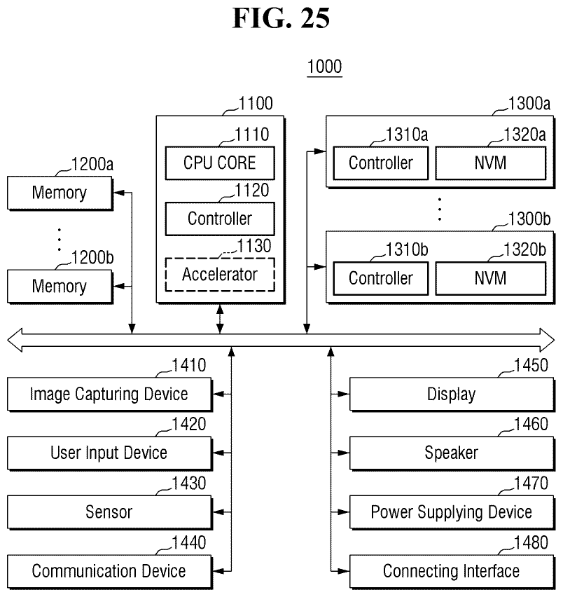

FIG. 25 is an illustrative diagram for explaining a system to which a storage device according to some embodiments of the inventive concepts is applied.

Referring to FIG. 25, a system 1000 may be a mobile system, such as a portable communication terminal, a mobile phone, a smartphone, a tablet personal computer (PC), a wearable device, a healthcare device, or an Internet of Things (IoT) device, but the present disclosure is not limited thereto. Alternatively, the system 1000 may also be a PC, a laptop computer, a server, a media player, or an automotive device (e.g., a navigation device).

The system 1000 may include a main processor 1100, memories 1200a and 1200b, and storage devices 1300a and 1300b. Additionally, the system 1000 may include at least one of an image capturing device 1410, a user input device 1420, a sensor 1430, a communication device 1440, a display 1450, a speaker 1460, a power supplying device 1470, and a connecting interface 1480.

The main processor 1100 may be configured to control the overall operation of the system 1000, particularly, the operations of various other components that form the system 1000. The main processor 1100 may be implemented as a general-purpose processor, a dedicated processor, or an application processor.

The main processor 1100 may include at least one CPU core 1110 and may further include a controller 1120 for controlling the memories 1200a and 1200b and/or the storage devices 1300a and 1300b. In some embodiments, the main processor 1100 may include a dedicated accelerator 1130 for high-speed data processing such as artificial intelligence (AI) data processing. The accelerator 1130 may include a graphics processing unit (GPU), a neural processing unit (NPU), and/or a data processing unit (DPU), and may be implemented as a separate independent chip from the other components of the main processor 1100.

The memories 1200a and 1200b may be configured to as the main memories of the system 1000 and may include volatile memories such as static random-access memories (SRAMs) and/or dynamic random-access memories (DRAMs), but may also include nonvolatile memories such as flash memories, phase-change random-access memories (PRAMs), and/or resistive random-access memories (RRAMs). The memories 1200a and 1200b may also be implemented within the same package as the main processor 1100.

The storage devices 1300a and 1300b may be configured to function as nonvolatile storage devices for storing data regardless of power supply status and may have a relatively large storage capacity compared to the memories 1200a and 1200b. The storage devices 1300a and 1300b may include controllers 1310a and 1310b, respectively, and nonvolatile memories 1320a and 1320b, respectively, which store data under the control of the controllers 1310a and 1310b, respectively. The nonvolatile memories 1320a and 1320b may include two-dimensional (2D) or three-dimensional (3D) V-NAND flash memories, but may also include other types of nonvolatile memories such as PRAMs and RRAMs.

The storage devices 1300a and 1300b may be included in the system 1000 while being physically separated from the main processor 1100 or implemented within the same package as the main processor 1100. Furthermore, the storage devices 1300a and 1300b may be implemented in the form of SSDs or memory cards and may be detachably connected to the other components of the system 1000 through an interface such as the connecting interface 1480 that will be described later. The storage devices 1300a and 1300b may correspond to the storage device 10 of FIG. 1, and the controllers 1310a and 1310b and the nonvolatile memories 1320a and 1320b may correspond to the memory controller 200 and the nonvolatile memory device 300, respectively, of FIG. 1.

The image capturing device 1410 may be configured to capture optical data, such as still images and/or videos; and may be, e.g., a camera, camcorder, webcam, etc.

The user input device 1420 may be configured to receive various types of data input from the user of the system 1000 and may be, e.g., a touchpad, keypad, keyboard, mouse, microphone, etc.

The sensor 1430 may detect various types of physical quantities that can be acquired from the external environment of the system 1000 and may convert the detected physical quantities into electrical signals. The sensor 1430 may include a temperature sensor, pressure sensor, light sensor, position sensor, acceleration sensor, biosensor, gyroscope, etc.

The communication device 1440 may be configured to transmit and receive signals between the system 1000 and other devices outside the system 1000 according to various communication protocols. The communication device 1440 may be (and/or be configured to include), e.g., an antenna, a transceiver, a modem, etc.

The display 1450 and the speaker 1460 may function as output devices that provide visual information and auditory information, respectively, to the user of the system 1000.

The power supplying device 1470 may be configured to convert power supplied from an embedded battery (not illustrated) and/or an external power source to supply power to the components of the system 1000.

The connecting interface 1480 may be configured to a connection between the system 1000 and an external device connected to the system 1000 to exchange data with the system 1000. The connecting interface 1480 may be implemented using various interface methods such as Advanced Technology Attachment (ATA), Serial ATA (SATA), external SATA (e-SATA), Small Computer Small Interface (SCSI), Serial Attached SCSI (SAS), Peripheral Component Interconnection (PCI), PCI express (PCIe), NVMe, IEEE 1394, Universal Serial Bus (USB), SD, Multi-Media Card (MMC), embedded MMC (eMMC), UFS, embedded UFS (eUFS), and CF.

Although embodiments of the present disclosure have been described with reference to the accompanying drawings, embodiments of the present disclosure are not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

What is claimed is:

1. A memory controller comprising:
a cache manager configured to receive a logical block address (LBA) from a host and to separate the LBA into a plurality of logical page numbers (LPNs), the plurality of LPNs including at least a first LPN and a second LPN;
a physical striper configured to output a first signal that corresponds the first LPN to a first page of a nonvolatile memory device and corresponds the second LPN to a second page of the nonvolatile memory device, wherein the second page is different from the first page; and
a logical writer configured to receive the first and second LPNs from the cache manager, to receive the first signal from the physical striper, and to store data to the nonvolatile memory device by performing a write operation based on the first signal,
wherein the write operation includes a first write operation for first data to a first address of the nonvolatile memory device corresponding to the first LPN and then performs a second write operation for second data to a second address of the nonvolatile memory device corresponding to the second LPN, and
wherein the data is stored such that a read operation by the host includes a first read operation for the first data stored at the first address and then a second read operation for the second data stored at the second address.

2. The memory controller of claim 1, wherein a first data read time for the first data and a second data read time for the second data are different from each other.

3. The memory controller of claim 1, wherein the first and second data are written in a high-speed programming (HSP) scheme.

4. The memory controller of claim 1, wherein
the nonvolatile memory device includes one or more word lines, and
the logical writer is configured to collect the LPNs to generate a program unit, for performing the write operation, based on the collected LPNS.

5. The memory controller of claim 4, wherein the memory controller is configured to write multiple data corresponding to the program unit to a memory cell that is connected to a corresponding one of the word lines of the nonvolatile memory device.

6. The memory controller of claim 4, wherein
the nonvolatile memory device includes a first word line and a second word line adjacent to the first word line,
the plurality of LPNs further include a third LPN,
the physical striper is configured to correspond the third LPN to a third page of the nonvolatile memory device, and
the logical writer is configured to generate the program unit by collecting the first, the second, and the third LPNs, to write some of the data corresponding to the program unit to a first memory cell connected to the first word line, and to write some of a remainder of the data corresponding to the program unit to a second memory cell connected to the second word line.

7. The memory controller of claim 6, wherein
the logical writer is configured to performs a third write operation for a third address of the nonvolatile memory device that corresponds to the third LPN after the second write operation, and
wherein the data is stored such that the read operation by the host includes a third read operation for third data stored at the third address after the second read operation.

8. The memory controller of claim 7, wherein a third data read time for the third data is different from a first data read time for the first data, and the third data read time is different from a second data read time for the second data.

9. A storage device comprising:
a nonvolatile memory device including a memory cell array; and
a memory controller configured to receive a write request signal and data from a host and to control the nonvolatile memory device to write the received data to the memory cell array,
wherein the nonvolatile memory device includes first through third pages, the memory controller includes
a cache manager configured to receive a logical block address (LBA) from the host and to separate the LBA into a plurality of logical page numbers (LPNs), the plurality of LPNs including at least first through sixth LPNs,
a physical striper is configured to perform a grouping operation such that a first group, including the first through third LPNs, and a second group including the fourth through sixth LPNs are generated, the first through third LPNs respectively correspond to the first through third pages and the fourth through sixth LPNs respectively correspond to the first through third pages, and
a logical writer configured to receive the LPNs from the cache manager and to sequentially write first through sixth data, of the received data and respectively corresponding to the first through sixth LPNs, to the nonvolatile memory device by performing a write operation based on the grouping operation.

10. The storage device of claim 9, wherein the first through sixth data is written such that a read operation by the host sequentially reads the first through sixth data stored at the nonvolatile memory device.

11. The storage device of claim 9, wherein
the memory controller and the nonvolatile memory device are configured to communicate with each other via a plurality of channels, and
the memory controller is configured to
transmit the first data to the nonvolatile memory device through a first channel,
transmit the second data to the nonvolatile memory device through a second channel different from the first channel, and
transmit the third data to the nonvolatile memory device through a third channel different from both the first and second channels.

12. The storage device of claim 9, wherein
the nonvolatile memory device includes at least an N-th word line and an (N+1)-th word line, and
the first through sixth data are written to a memory cell connected to the N-th word line.

13. The storage device of claim 9, wherein
the memory cell array includes at least an N-th word line and an (N+1)-th word line,
the first, second, fourth, and fifth data are written to a first memory cell connected to the N-th word line, and
the third and sixth data are written to a second memory cell connected to the (N+1)-th word line.

14. The storage device of claim 9, wherein
the logical writer is configured to transmit a first signal to the physical striper in response to receipt of the LPNs from the cache manager,
in response to receiving the first signal, the physical striper is configured to perform the grouping operation and to transmit a second signal to the logical writer, and
the second signal includes the correspondence between the first through sixth LPNs and the first through third pages.

15. The storage device of claim 9, wherein a data read time for the first data is the same as a data read time for the fourth data and is different from a data read time for the second data.

16. A host-storage system comprising:
a host configured to transmit a write request signal, data, and a logical block address (LBA);
a nonvolatile memory device including a memory cell array and a plurality of word lines connected to the memory cell array; and
a memory controller configured to receive the write request signal, the data, and the LBA and to control a write operation to write the data to a memory cell, of the nonvolatile memory device, corresponding to the LBA,
wherein the memory controller includes
a cache manager configured to separate the LBA into logical page numbers (LPNs),
a logical writer configured to receive the one or more LPNs and to generate a program unit by collecting the LPNs on a page-by-page basis, and
a physical striper configured to group some of the LPNs into a first LPN group and some of a remainder of the LPNs into a second LPN group such that the first LPN group corresponds to a first page and the second LPN group corresponds to a second page different from the first page, and
wherein, when performing the write operation to the nonvolatile memory device based on the program unit, the logical writer is configured to initiate a write operation for the first page and then initiate a write operation for the second page before completing the write operation for the first page.

17. The host-storage system of claim 16, wherein
the first LPN group includes a first LPN corresponding to first data and a second LPN corresponding to second data,
the second LPN group includes a third LPN corresponding to third data,
the memory controller and the nonvolatile memory device are configured to communicate with each other via at least a first channel and a second channel,
the memory controller is configured to transmit the first data to the nonvolatile memory device via the first channel and to transmit the second and third data to the nonvolatile memory device via the second channel, and
the logical writer is configured to perform a write operation for the third data after the initiating of the write operation for the first data and before completing the write operation for the second data.

18. The host-storage system of claim 17, wherein
a data read time for the first data is the same as a data read time for the second data and is different from a data read time for the third data, and
the host is configured to perform a read operation for the third data after performing a read operation for the first data and before performing a read operation for the second data.

19. The host-storage system of claim 16, wherein
the logical writer is configured to generate a program unit based on the correspondence between the LPNs generated by the physical striper and the first and second pages, and
data included in the program unit are written to the first and second pages in a high-speed programming (HSP) scheme.

20. The host-storage system of claim 19, wherein
the memory cell array includes first and second word lines, which are connected to first and second memory cells, respectively,
data of the first page included in the program unit is written to the first memory cell, and
data of the second page is written to the second memory cell.
